(19) United States
(12) Patent Application Publication
(10) Pub. No.: US 2026/0173307 A1
(43) Pub. Date: Jun. 18, 2026

(54) HEAT DISSIPATION DEVICE, HEAT DISSIPATION SYSTEM AND ELECTRONIC DEVICE

(71) Applicant: LANNER ELECTRONICS INC., New Taipei City (TW)

(72) Inventors: KUANG-HONG WU, New Taipei City (TW); YEN-YIN YU, Yilan County (TW); JUNG-LIN LU, New Taipei City (TW); TSE-MIN LIN, New Taipei City (TW); YAO-SHENG HUANG, New Taipei City (TW); CHI-CHUAN WANG, Hsinchu County (TW); CHUN-YI KUO, Hsinchu City (TW); YONG-DONG ZHANG, Hsinchu City (CN); HSIANG-HO HUANG, New Taipei City (TW)

(73) Assignee: LANNER ELECTRONICS INC., New Taipei City (TW)

(21) Appl. No.: 19/212,986

(22) Filed: May 20, 2025

(30) Foreign Application Priority Data
Dec. 13, 2024 (TW) 113148553

(51) Int. Cl. H05K 7/20; G06F 1/20

(52) U.S. Cl. CPC H05K 7/20254; G06F 1/20; H05K 7/20272; G06F 2200/201

(57) ABSTRACT

A heat dissipation device is disclosed, comprising a housing case having an inlet port and outlet port, a supporting body (SB), a heat pipe (HP), and a heat sink, a first partition plate (PP) and a second partition plate (PP), of which the heat sink includes a plurality of flow channels. Particularly, the first PP, the second PP, and the SB makes a buffer space be formed in the housing case. Moreover, the HP having one inlet orifice and one outlet orifice is disposed on the SB, and the inlet orifice is connected to the inlet port. As such, a liquid stored in the reservoir is able to flow into the HP, subsequently flows along the HP, and then gets into the buffer space via the outlet orifice. Consequently, the liquid flows and passes the flow channels, thereby flowing back into the reservoir via the outlet port.

### CROSS-REFERENCE TO RELATED APPLICATIONS

This application claims the priority and benefit of Taiwan patent application No. 113148553, filed on December, 13, 2024, the entire contents of which are incorporated herein by reference.

### BACKGROUND OF THE INVENTION

### 1. Field of the Invention

The present invention relates to the technology filed of heat dissipation devices, and more particularly, to a heat dissipation device for use in liquid cooling application.

### 2. Description of the Prior Art

It is known that there are a variety of computer systems developed so as to be launched on the market, including desktop computer, laptop computer, all-in-one computer, industrial computer, server computer, and video game console. In addition, it is also aware of that the computer system is provided with at least one heat dissipation device (or called as cooling device) therewithin, so as to assist in cooling down the working temperature of the electronic chip like CPU and the at least one electronic module including solid-state drive. For example, a traditional heat dissipation device 1a with reference to FIG. 1 comprises a heat conductive block 11a, a heat sink 12a, at least one heat pipe 13a, and a cooling fan 14a, of which the heat conductive block 11a is disposed on a heat source such as CUP or GPU, the heat pipe 13a connected between the heat conductive block 11a and the heat sink 12a, and the cooling fan 14a disposed on the fins of the heat sink 12a.

It is worth further explaining that, the computing speed and data transfer rate of the computer system's CPU and GPU are correspondingly enhanced with the development and application of cloud computing, video game streaming service and AAA games, thereby leading the traditional heat dissipation device 1a to expose the inadequate ability in cooling down the working temperature of the computer system's CPU and GPU. Accordingly, Taiwan patent No. I821055 has disclosed an integrated liquid cooling heat dissipation system to replacing the traditional heat dissipation device 1a for application in the computer system that uses high performance computing CPU and/or GPU.

As described in more detail below, the disclosed integrated liquid cooling heat dissipation system comprises a heat conductive block, a heat sink, at least one heat pipe, a cooling fan, and a reservoir having an inlet port and an outlet port, of which the heat conductive block is disposed on a heat source such as CUP or GPU. Moreover, the heat sink is disposed on the heat conductive block, and consists of a plurality of plate fins. In addition, the heat pipe is arranged to pass through the plate fins, and is connected to the inlet port and the outlet port of the reservoir. When working normally, a specific liquid stored in the reservoir flows into the heat pipe, then flows along the heat pipe, thereby flowing back into the reservoir.

According to practical experience, many drawbacks of the integrated liquid cooling heat dissipation system have been uncovered during use. To be more specific, the drawbacks, including the liquid flowing in the heat pipe being unable to directly contact the plate fins and each of the plate fins contacting the heat pipe by a limited contact area, lead the integrated liquid cooling heat dissipation system to still has room for improvement in heat dissipation efficiency. In view of that, inventors of the present application have made great efforts to make inventive research and eventually provided a heat dissipation device for use in liquid cooling application.

### SUMMARY OF THE INVENTION

The primary objective of the present invention is to provide a heat dissipation device for use in liquid cooling application. The heat dissipation device comprises a housing case, a supporting body, a heat pipe, and a heat sink consisting of a plurality of plate fins, a first partition plate and a second partition plate, of which the housing case has an inlet port and an outlet port, and there is one flow channel formed by any two of the plurality of plate fins. Particularly, the first partition plate, the second partition plate, and the supporting body is disposed in the housing case, thereby making a buffer space be formed in the housing case. Moreover, the heat pipe having one inlet orifice and one outlet orifice is disposed on the supporting body, and the inlet orifice is connected to the inlet port of the housing case, such that the outlet orifice and the flow channels all communicate with the buffer space. As such, a liquid stored in the reservoir is able to flow into the heat pipe, subsequently flows along the heat pipe, and then gets into the buffer space via the outlet orifice. Consequently, the liquid flows and passes the flow channels, thereby eventually flowing back into the reservoir via the outlet port of the housing case.

It is worth mentioning again that, the liquid flowing into the buffer space firstly passes through the flow channels of the heat sink before flowing back into the reservoir via the outlet port of the housing case. In other words, the plate fins of the heat sink comprehensively contact the liquid in the housing case, such that the heat dissipation device according to the present invention performs outstanding heat dissipation efficiency superior to that of the conventional integrated liquid cooling heat dissipation system.

In practical application, the heat dissipation device is suitable for being integrated in a hybrid liquid and air cooling system or an immersion cooling system.

In order to achieve the aforementioned objective, one embodiment of the heat dissipation device is provided, which comprises:
a housing case, comprising an upper-side plate, a first side plate, a second side plate, a third side plate, a fourth side plate, wherein the first side plate is connected to the second side plate and the upper-side plate, the second side plate is connected to the third side plate and the upper-side plate, the third side plate is connected to the fourth side plate and the upper-side plate, the fourth side plate is connected to the first side plate and the upper-side plate, and the first side plate and the second side plate are provided with a first hole and a second hole thereon, respectively;
a heat pipe, being disposed in the housing case, and having an inlet segment and an outlet segment parallel to the inlet segment, wherein the inlet segment has an inlet orifice in connection with the first hole, the outlet segment has an outlet orifice that faces and is adjacent to third side plate, and a first side and a second side of the outlet segment face the fourth side plate and the second side plate, respectively;
a heat sink, being disposed in the housing case so as to be stacked on the heat pipe, and comprising a plate and M numbers of plate fins in connection with the plate;
a first partition plate, being disposed in the housing case, connected to the heat sink and adjacent to the first side of the outlet segment; and
a second partition plate, being disposed in the housing case, connected to the heat sink, and adjacent to the second side of the outlet segment;
wherein the plate is connected the upper-side plate, and the M numbers of plate fins and the upper-side plate enclose M−1 numbers of flow channels;
wherein the first partition plate stays between the first side of the outlet segment and the fourth side plate, and is adjacent to the outlet orifice of the outlet segment;
wherein the second partition plate stays between the second side of the outlet segment and the second side plate.

In one embodiment, the housing case comprises:
a cover, consisting of the upper-side plate, the first side plate, the second side plate, the third side plate, and the fourth side plate, and having an opening; and
a bottom plate, being connected to the cover so as to shield the opening, such that the first partition plate and the second partition plate are all connected between the bottom plate and the upper-side plate.

In an optional embodiment, the heat dissipation device according to the present invention further comprises:
a supporting body, being disposed in the housing case so as to be disposed on the bottom plate, and comprising:
a base;
N+3 numbers of protrusion members, being formed on the base, and all having a long shape; and
N+2 numbers of grooves, being formed on the base;
wherein any two said protrusion members and the base enclose one said groove;
wherein M and N are both a positive integer.

In one embodiment, the first partition plate is further connected the third side plate, a M-th plate fin of the M numbers of plate fins and the supporting body, and the second partition plate is further connected the first side plate, a first plate fin of the M numbers of plate fins and the supporting body.

In one embodiment, the bottom plate, the third side plate, the first partition plate, the M-th plate fin, the first plate fin, the supporting body, the second partition plate, the second side plate, the first side plate, and the upper-side plate define a buffer space in the housing case.

In one embodiment, the heat pipe comprises:
N+2 numbers of long straight segments; and
N+1 numbers of connection segments, all having a curved shape;
wherein any one said connection segment is connected between two said long straight segments, and the N+2 numbers of long straight segments are received by the N+2 numbers of grooves of the supporting body.

In one embodiment, each of the N+2 numbers of long straight segments is provided with a metal spring therewithin, and an inner wall of each of the N+2 numbers of long straight segments is coated with a capillary structure layer thereon.

In one embodiment, the N+2 numbers of long straight segments comprise the inlet segment and the outlet segment, and further comprise:
N numbers of middle segments, wherein each of the N numbers of middle segments is parallel to the outlet segment.

In one embodiment, each of the M numbers of plate fins has a first short side, a second short side, a first long side, and a second long side, the first long side is connected to the plate, and the second long side are provided with N+2 numbers of notches, such that the inlet segment, the outlet segment and the N numbers of middle segments are embedded in the N+2 numbers of notches, respectively.

In further another one optional embodiment, the heat dissipation device according to the present invention further comprises:
an inlet port, being connected to the first hole, and being adapted for connecting a first tube; and
an outlet inlet port, being connected to the second hole, and being adapted for connecting a second tube;
wherein the first tube and the second tube are connected to a reservoir that contains a liquid, such that the liquid is able to flow into the heat pipe via the first tube, subsequently flows into the buffer space through the outlet orifice of the heat pipe, and then passes through the M−1 numbers of flow channels, thereby eventually flowing back into the reservoir via the second tube.

In addition, an embodiment of a heat dissipation system is also disclosed, which comprises:
a reservoir;
a first tube connected to the reservoir;
a second tube connected to the reservoir; and
the aforesaid heat dissipation device, being connected to the first tube and the second tube.

Furthermore, an embodiment of an electronic device is also disclosed, which comprises:
a chassis;
at least one electronic device accommodated in the chassis;
at least one electronic module accommodated in the chassis;
a reservoir, being disposed in the chassis, or being arranged to stay outside the chassis;
a first tube connected to the reservoir;
a second tube connected to the reservoir; and
the aforesaid heat dissipation device, being accommodated in the chassis, and being connected to the first tube and the second tube.

In one embodiment, the electronic device is selected from a group consisting of server computer, Ethernet switch, Ethernet gateway, embedded computer, single board computer, industrial computer, desktop computer, all-in-one computer, on-board computer, host computer of security surveillance system, video game console, and host computer of arcade game machine.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 shows a stereo diagram of a traditional heat dissipation device.

FIG. 2 shows a stereo diagram of a heat dissipation device according to the present invention.

FIG. 3 shows a stereo diagram of a heat dissipation system according to the present invention.

FIG. 4A shows a first exploded view of the heat dissipation device according to the present invention.

FIG. 4B shows a second exploded view of the heat dissipation device according to the present invention.

FIG. 5 shows a perspective view of the heat dissipation device according to the present invention.

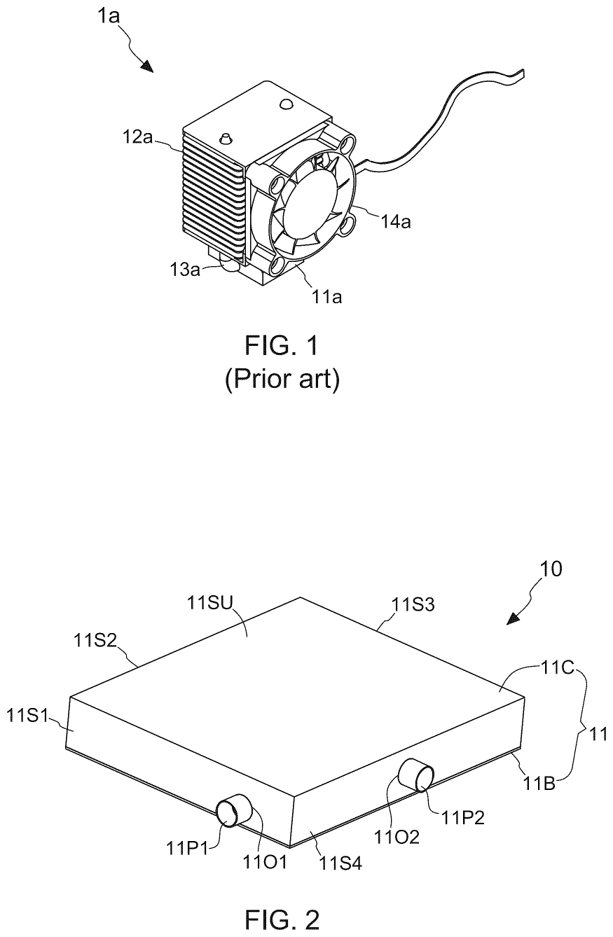

### DETAILED DESCRIPTION OF THE PREFERRED EMBODIMENTS

To more clearly describe a heat dissipation device, a heat dissipation system including the heat dissipation device and an electronic device including the heat dissipation system according to the present invention, embodiments of the present invention will be described in detail with reference to the attached drawings hereinafter.

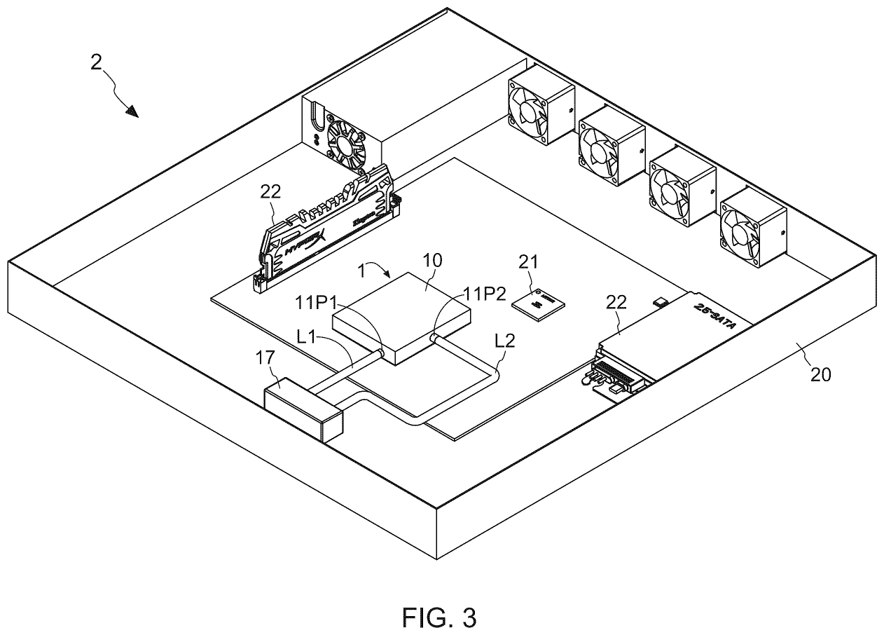

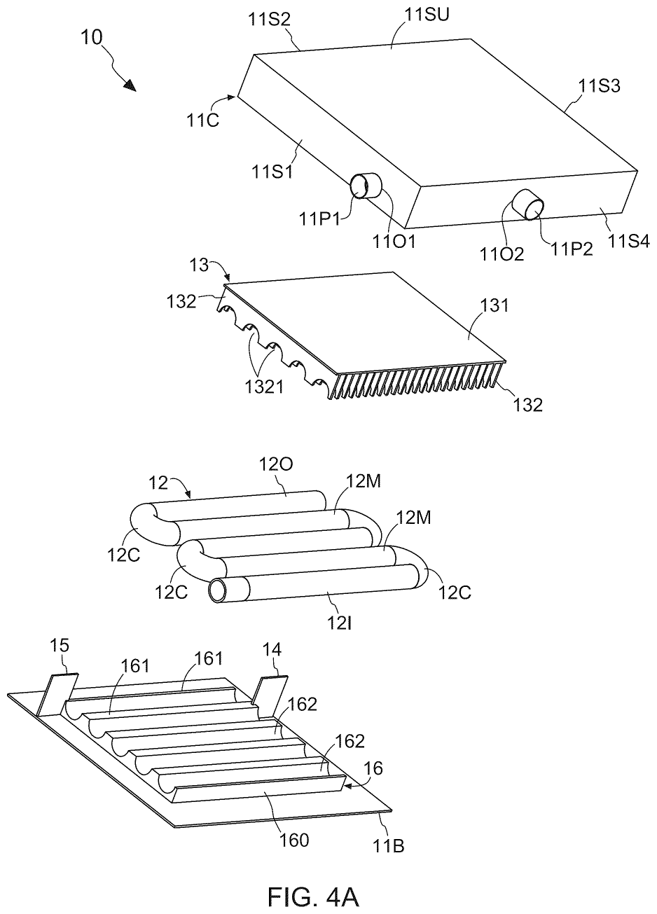

With reference to FIG. 2 and FIG. 3, there are a stereo diagram of a heat dissipation device according to the present invention and a stereo diagram of a heat dissipation system including the heat dissipation device provided. As FIG. 2 and FIG. 3 show, the heat dissipation device 10 according to the present invention is adapted for use in constituting a heat dissipation system 1 with a reservoir 17. To be more specific, the reservoir 17 is connected to a first tube L1 and a second tube L2, and the heat dissipation device 10 has an inlet port 11P1 and an outlet port 11P2, wherein the inlet port 11P1 and the outlet port 11P2 are in connection with the first tube L1 and the second tube L2, respectively. In practical application, the heat dissipation system 1 is integrated in an electronic device 2 comprising a chassis 20, at least one electronic chip 21 such as CPU and/or GPU and at least one electronic module 22 including solid-state drive (SSD), so as to assist in cooling down the working temperature of the electronic chip 21 and the electronic module 22. In any practical embodiments, the electronic device 2 can be, but is not limited to server computer, Ethernet switch, Ethernet gateway, embedded computer, single board computer, industrial computer, desktop computer, all-in-one computer, on-board computer, host computer of security surveillance system, video game console, or host computer of arcade game machine.

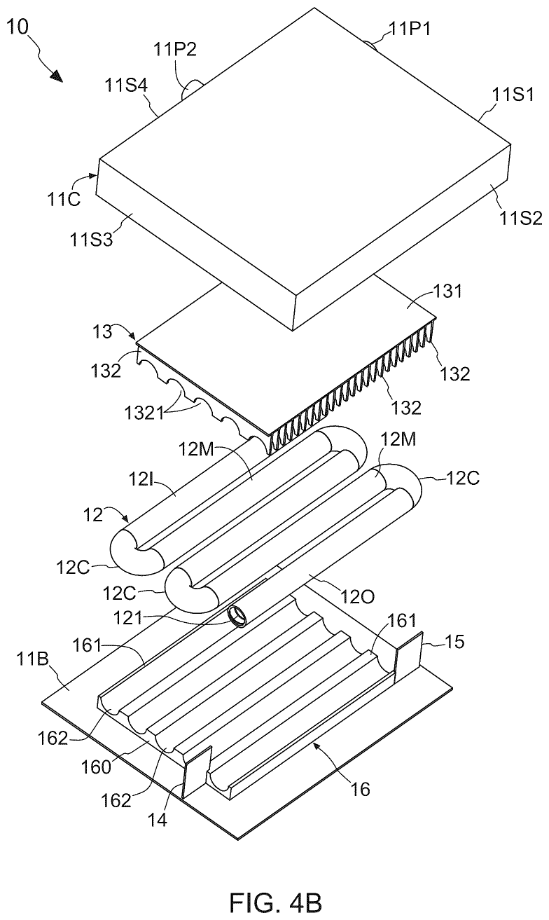

FIG. 4A and FIG. 4B illustrate a first exploded view and a second exploded view of the heat dissipation device according to the present invention. As FIG. 2, FIG. 4A and FIG. 4B show, the heat dissipation device 10 comprises a housing case 11, a supporting body 16, a heat pipe 12, a heat sink 13, a first partition plate 14, and a second plate 15, of which the housing case 11 consists of a bottom plate 11B and a cover 11C. As described in more detail below, the cover 11C comprises an upper-side plate 11S, a first side plate 11S1, a second side plate 11S2, a third side plate 11S3, a fourth side plate 11S4, wherein the first side plate 11S1 is connected to the second side plate 11S2 and the upper-side plate 11SU, the second side plate 11S2 is connected to the third side plate 11S3 and the upper-side plate 11SU, the third side plate 11S3 is connected to the fourth side plate 11S4 and the upper-side plate 11SU, and the fourth side plate 11S4 is connected to the first side plate 11S1 and the upper-side plate 11SU. Moreover. the first side plate 11S1 and the second side plate 11S2 are provided with a first hole 11O1 and a second hole 11O2 thereon, respectively

As FIG. 2, FIG. 3, FIG. 4A and FIG. 4B show, the first hole 11O1 is connected to the inlet port 11P1, and the second hole 11O2 is in connection with the outlet port 11P2. In addition, the upper-side plate 11S, the first side plate 11S1, the second side plate 11S2, the third side plate 11S3, and the fourth side plate 11S4 enclose an opening, and the bottom plate 11B is connected to the cover 11C so as to shield the opening, such that the first partition plate 14 and the second partition plate 15 are all connected between the bottom plate 11B and the upper-side plate 11SU.

On the other hand, the supporting body 16 is disposed in the housing case 11 so as to be disposed on the bottom plate 11B, and comprises: a base 160, N+3 numbers of protrusion members 161 and N+3 numbers of protrusion members 161, of which the N+3 numbers of protrusion members 161 are formed on the base 160, and all having a long shape. Similarly, the N+2 numbers of grooves 162 are also formed on the base 160. With reference to FIG. 4A and FIG. 4B, it is easily understood that M and N are both a positive integer, and any two said protrusion members 161 and the base 160 enclose one said groove 162. In other words, any one said groove 162 is formed between two said protrusion members 161 and the base 160.

According to the present invention, the heat pipe 12 is disposed in the housing case 11 so as to be stacked on the supporting body 16. In one embodiment, the heat pipe 12 comprises N+2 numbers of long straight segments comprising an inlet segment 12I, an outlet segment 12O and N numbers of middle segments 12M and N+1 numbers of connection segments 12C, of which the N+1 numbers of connection segments 12C all have a curved shape. As FIG. 4A and FIG. 4B show, any one said connection segment 12C is connected between two said long straight segments (12I, 12O, 12M), and the N+2 numbers of long straight segments (12I, 12O, 12M) are received by the N+2 numbers of grooves 162 of the supporting body 16. In the structure of the heat pipe 12, the outlet segment 12O is parallel to each of the N numbers of middle segments 12M and the inlet segment 12I, and has an outlet orifice. In contrast to the outlet segment 12O, the inlet segment 12I has an inlet orifice in connection with the first hole 11O1. To be more specific, the outlet orifice of the outlet segment 12O faces and is adjacent to the third side plate 11S3, and a first side and a second side of the outlet segment 12O face the fourth side plate 11S4 and the second side plate 11S2, respectively. It is worth further explaining that, each of the N+2 numbers of long straight segments (12I, 12O, 12M) is provided with a metal spring 121 therewithin, and an inner wall of each of the N+2 numbers of long straight segments (12I, 12O, 12M) is coated with a capillary structure layer thereon.

As FIG. 4A and FIG. 4B show, the heat sink 13 is disposed in the housing case 11 so as to be stacked on the heat pipe 12, and comprises a plate 131 and M numbers of plate fins 132 in connection with the plate 131. As described in more detail below, each of the M numbers of plate fins 132 has a first short side, a second short side, a first long side, and a second long side, of which the first long side is connected to the plate 131, and the second long side are provided with N+2 numbers of notches 1321, such that the inlet segment 12I, the outlet segment 12O and the N numbers of middle segments 12M are embedded in the N+2 numbers of notches 1321, respectively. Moreover, the plate 131 is connected the upper-side plate 11SU in the housing case 11, and the M numbers of plate fins 132 and the upper-side plate 11SU enclose M−1 numbers of flow channels. In other words, any one said flow channel is formed between two said plate fins 132 and the upper-side plate 11SU.

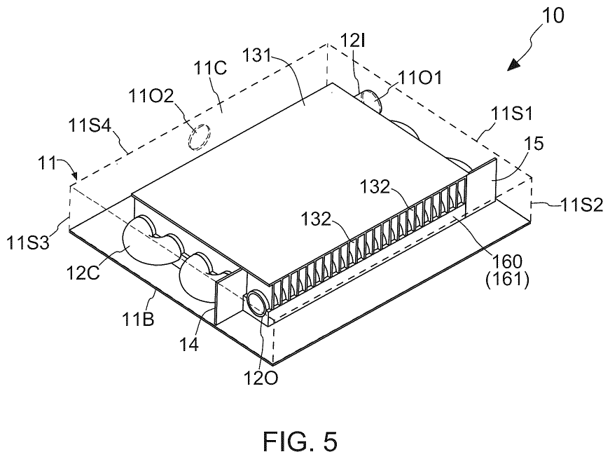

FIG. 5 shows a perspective view of the heat dissipation device according to the present invention. It is noted that, the outline of the cover 11C, the first hole 11O1 and the second hole 11O2 are depicted by dashed lines in FIG. 5. As described in more detail below, the first partition plate 14 is disposed in the housing case 11, connected to the heat sink 13 and adjacent to the first side of the outlet segment 12O. To be more specific, the first partition plate 14 stays between the first side of the outlet segment 12O and the fourth side plate 11S4 in the housing case 11, and is adjacent to the outlet orifice of the outlet segment 12O. In contrast to the first partition plate 14, the second partition plate 15 is disposed in the housing case 11, connected to the heat sink 13 and adjacent to the second side of the outlet segment 12O. Moreover, as FIG. 4A, FIG. 4B and FIG. 5 show, the second partition plate 15 stays between the second side of the outlet segment 12O and the second side plate 11S2.

According to the present invention, the first partition plate 14 is further connected the third side plate 11S3, a M-th plate fin 132 of the M numbers of plate fins 132 and the supporting body 16, and the second partition plate 15 is further connected the first side plate 11S1, a first plate fin 132 of the M numbers of plate fins 132 and the supporting body 16. As such, the bottom plate 11B, the third side plate 11S3, the first partition plate 14, the M-th plate fin 132, the first plate fin 132, the supporting body 16, the second partition plate 15, the second side plate 11S2, the first side plate 11S1, and the upper-side plate 11SU define a buffer space in the housing case 11.

When working normally, a liquid stored in the reservoir 17 is able to flow into the heat pipe 12 via first tube L1 and the inlet port 11P1, subsequently flows along the heat pipe 12, and then gets into the buffer space via the outlet orifice of the outlet segment 12O. Consequently, the liquid flows and passes the M−1 numbers of flow channels, thereby eventually flowing back into the reservoir via the outlet port 11P2 and the second tube L2.

It is worth mentioning again that, the liquid flowing into the buffer space firstly passes through the flow channels of the heat sink 13 before flowing back into the reservoir 17 via the outlet port 11P2 of the housing case 11. In other words, the plate fins 132 of the heat sink 13 comprehensively contact the liquid in the housing case 11, such that the heat dissipation device 10 according to the present invention performs outstanding heat dissipation efficiency superior to that of the conventional integrated liquid cooling heat dissipation system.

Besides, it is worth mentioning that the heat dissipation device 10 according to the present invention is suitable for being integrated in a hybrid liquid and air cooling system or an immersion cooling system in practical application.

Therefore, in above descriptions, the heat dissipation device 10 according to the present invention has been introduced completely and clearly. Moreover, the heat dissipation system 1 including the heat dissipation device 10 and the electronic device 2 including the heat dissipation system 1 have also been introduced completely and clearly.

To be particularly emphasized that, the above description is made on embodiments of the present invention. However, the embodiments are not intended to limit scope of the present invention, and all equivalent implementations or alterations within the spirit of the present invention still fall within the scope of the present invention.

What is claimed is:

1. A heat dissipation device, comprising:
a housing case, comprising an upper-side plate, a first side plate, a second side plate, a third side plate, a fourth side plate, wherein the first side plate is connected to the second side plate and the upper-side plate, the second side plate is connected to the third side plate and the upper-side plate, the third side plate is connected to the fourth side plate and the upper-side plate, the fourth side plate is connected to the first side plate and the upper-side plate, and the first side plate and the second side plate are provided with a first hole and a second hole thereon, respectively;
a heat pipe, being disposed in the housing case, and having an inlet segment and an outlet segment parallel to the inlet segment, wherein the inlet segment has an inlet orifice in connection with the first hole, the outlet segment has an outlet orifice that faces and is adjacent to third side plate, and a first side and a second side of the outlet segment face the fourth side plate and the second side plate, respectively;
a heat sink, being disposed in the housing case so as to be stacked on the heat pipe, and comprising a plate and M numbers of plate fins in connection with the plate;
a first partition plate, being disposed in the housing case, connected to the heat sink and adjacent to the first side of the outlet segment; and
a second partition plate, being disposed in the housing case, connected to the heat sink and adjacent to the second side of the outlet segment;
wherein the plate is connected the upper-side plate, and the M numbers of plate fins and the upper-side plate enclose M-1 numbers of flow channels;
wherein the first partition plate stays between the first side of the outlet segment and the fourth side plate, and is adjacent to the outlet orifice of the outlet segment;
wherein the second partition plate stays between the second side of the outlet segment and the second side plate.

2. The heat dissipation device of claim 1, wherein the housing case comprises:
a cover, consisting of the upper-side plate, the first side plate, the second side plate, the third side plate, and the fourth side plate, and having an opening; and
a bottom plate, being connected to the cover so as to shield the opening, such that the first partition plate and the second partition plate are all connected between the bottom plate and the upper-side plate.

3. The heat dissipation device of claim 2, further comprising:
a supporting body, being disposed in the housing case so as to be disposed on the bottom plate, and comprising:
a base;
N+3 numbers of protrusion members, being formed on the base, and all having a long shape; and
N+2 numbers of grooves, being formed on the base;
wherein any two said protrusion members and the base enclose one said groove;
wherein M and N are both a positive integer.

4. The heat dissipation device of claim 3, wherein the first partition plate is further connected the third side plate, a M-th plate fin of the M numbers of plate fins and the supporting body, and the second partition plate is further connected the first side plate, a first plate fin of the M numbers of plate fins and the supporting body.

5. The heat dissipation device of claim 4, wherein the bottom plate, the third side plate, the first partition plate, the M-th plate fin, the first plate fin, the supporting body, the second partition plate, the second side plate, the first side plate, and the upper-side plate define a buffer space in the housing case.

6. The heat dissipation device of claim 3, wherein the heat pipe comprises:
N+2 numbers of long straight segments; and
N+1 numbers of connection segments, all having a curved shape;
wherein any one said connection segment is connected between two said long straight segments, and the N+2 numbers of long straight segments are received by the N+2 numbers of grooves of the supporting body.

7. The heat dissipation device of claim 6, wherein each of the N+2 numbers of long straight segments is provided with a metal spring therewithin, and an inner wall of each of the N+2 numbers of long straight segments is coated with a capillary structure layer thereon.

8. The heat dissipation device of claim 6, wherein the N+2 numbers of long straight segments comprise the inlet segment and the outlet segment, and further comprise:
N numbers of middle segments, wherein each of the N numbers of middle segments is parallel to the outlet segment.

9. The heat dissipation device of claim 8, wherein each of the M numbers of plate fins has a first short side, a second short side, a first long side, and a second long side, the first long side is connected to the plate, and the second long side are provided with N+2 numbers of notches, such that the inlet segment, the outlet segment and the N numbers of middle segments are embedded in the N+2 numbers of notches, respectively.

10. The heat dissipation device of claim 8, further comprising:
an inlet port, being connected to the first hole, and being adapted for connecting a first tube; and
an outlet inlet port, being connected to the second hole, and being adapted for connecting a second tube;
wherein the first tube and the second tube are connected to a reservoir that contains a liquid, such that the liquid is able to flow into the heat pipe via the first tube, subsequently flows into the buffer space through the outlet orifice of the heat pipe, and then passes through the M−1 numbers of flow channels, thereby eventually flowing back into the reservoir via the second tube.

11. A heat dissipation system, comprising:
a reservoir;
a first tube connected to the reservoir;
a second tube connected to the reservoir; and
said heat dissipation device according to claim 1, being connected to the first tube and the second tube.

12. An electronic device, comprising
a chassis;
at least one electronic device accommodated in the chassis;
at least one electronic module accommodated in the chassis;
a reservoir, being disposed in the chassis, or being arranged to stay outside the chassis;
a first tube connected to the reservoir;
a second tube connected to the reservoir; and
said heat dissipation device according to claim 1, being accommodated in the chassis, and being connected to the first tube and the second tube.

13. The electronic device of claim 12, wherein the electronic device is selected from a group consisting of server computer, Ethernet switch, Ethernet gateway, embedded computer, single board computer, industrial computer, desktop computer, all-in-one computer, on-board computer, host computer of security surveillance system, video game console, and host computer of arcade game machine.
